(19) United States
(12) Patent Application Publication
(10) Pub. No.: US 2017/0011974 A1
(43) Pub. Date: Jan. 12, 2017

(54) SUBSTRATE PROCESSING APPARATUS, METHOD FOR MANUFACTURING SEMICONDUCTOR DEVICE, AND RECORDING MEDIUM

(71) Applicant: HITACHI KOKUSAI ELECTRIC INC., Tokyo (JP)

(72) Inventors: Takashi YOKAWA, Toyama-shi (JP); Yasuhiro MIZUGUCHI, Toyama-shi (JP); Makoto NOMURA, Toyama-shi (JP); Kazuhito SAITO, Toyama-shi (JP)

(73) Assignee: HITACHI KOKUSAI ELECTRIC INC., Tokyo (JP)

(21) Appl. No.: 15/273,875

(22) Filed: Sep. 23, 2016

Related U.S. Application Data
(63) Continuation of application No. PCT/JP2015/057490, filed on Mar. 13, 2015.

(30) Foreign Application Priority Data
Mar. 25, 2014 (JP) 2014-061457

(51) Int. Cl. H01L 21/66; H01L 21/324; H01L 21/67; C23C 16/52; C23C 14/54

(52) U.S. Cl. CPC H01L 22/12; C23C 16/52; C23C 14/54; H01L 21/67103; H01L 21/67248; H01L 21/324

(57) ABSTRACT

A substrate processing apparatus includes a substrate heating part, a power supply part and a control device. The control device measures a temperature of the substrate while controlling the substrate heating part such that the temperature of the substrate reaches a first control temperature higher than the target temperature using power supplied by the power supply part. The device measures the temperature of the substrate for a second control temperature lower than the target temperature, and selects the power ratio value providing the best temperature uniformity in the plane of the substrate and a temperature average value for the selected power ratio value from a result of the measurement. The device calculates a control temperature and the power ratio value for the target temperature based on the selected temperature average value and the power ratio value for each of the first and second control temperature.

### CROSS-REFERENCE TO RELATED APPLICATION

This application is a Continuation Application of PCT International Application No. PCT/JP2015/057490, filed Mar. 13, 2015, which claimed the benefit of Japanese Patent Application No. 2014-061457, filed on Mar. 25, 2014, the entire contents of which are incorporated herein by reference.

### TECHNICAL FIELD

The present disclosure relates to a substrate processing apparatus, a method for manufacturing a semiconductor device, and a recording medium.

### BACKGROUND

In general, in the field of semiconductor manufacturing, a substrate processing apparatus is being used to form a film on a semiconductor substrate by means of a film forming process. This kind of substrate processing apparatus performs a process of heating the substrate, for example, by means of a heater to which predetermined power is supplied.

In such an apparatus, process conditions for processing a product substrate are determined prior to performing the processing of the product substrate. Among the process conditions, temperature uniformity at the time of substrate heating is an important factor having direct relation to substrate thickness uniformity and film composition uniformity. The substrate temperature uniformity is calculated from results of measurement of a temperature at which the substrate is heated, based on a set power ratio value.

Values obtained from design values or from many years of experience of an operator have been used as initially set power ratio values. However, since unpredictable conditions exist in an actual heating process, it is necessary for the operator to repeat by trial and error based on design values or empirical values in order to obtain an optimal power ratio value, requiring prolonged experiments.

### SUMMARY

The present disclosure provides some embodiments of a novel technique which is capable of further shortening the time taken to acquire a control factor including a power ratio value to achieve desired temperature uniformity, as compared to conventional techniques.

According to one embodiment of the present disclosure, there is provided a substrate processing apparatus including: a substrate heating part including a plurality of regions and being configured to heat a substrate; a power supply part configured to supply power to the plurality of regions:, and a control device configured to adjust the power supplied by the power supply part and control the substrate heating part such that the temperature of the substrate reaches a predetermined target temperature, wherein the control device: measures a temperature of the substrate while controlling the substrate heating part such that the temperature of the substrate reaches a first control temperature higher than the target temperature using power supplied by the power supply part to each of the plurality of regions, the power supplied to one of the plurality of regions being determined according to the product of reference power supplied to the other of the plurality of regions and a power ratio value, and selects the power ratio value providing the best temperature uniformity in the plane of the substrate among results of the measurement and a temperature average value for the selected power ratio value; measures the temperature of the substrate for a second control temperature lower than the target temperature, like the first control temperature, and selects the power ratio value providing the best temperature uniformity in the plane of the substrate among results of the measurement and a temperature average value for the selected power ratio value; and calculates a control temperature and the power ratio value for the target temperature based on the selected temperature average value and the power ratio value for each of the first control temperature and the second control temperature.

### BRIEF DESCRIPTION OF THE DRAWINGS

FIG. 1 is a view illustrating a processing furnace of a substrate processing apparatus suitably used in an embodiment of the present disclosure.

FIG. 2 is a perspective view illustrating a substrate heating mechanism of the substrate processing apparatus suitably used in an embodiment of the present disclosure.

FIG. 3 is a view illustrating a processing furnace of the substrate processing apparatus suitably used in an embodiment of the present disclosure.

FIG. 4 is a view illustrating the configuration of the substrate processing apparatus suitably used in an embodiment of the present disclosure.

FIG. 5 is a partial sectional view illustrating an upper portion of a substrate processing apparatus main body shown in the substrate processing apparatus suitably used in an embodiment of the present disclosure.

FIG. 6 is a partial sectional view illustrating a side portion of the substrate processing apparatus main body shown in the substrate processing apparatus suitably used in an embodiment of the present disclosure.

FIG. 7 is a view illustrating the configuration of the processing furnace of the substrate processing apparatus suitably used in an embodiment of the present disclosure.

FIG. 8 is a plan view illustrating an example of arrangement of temperature detectors connected to a substrate.

FIG. 9 is a view illustrating the configuration of the substrate processing apparatus suitably used in an embodiment of the present disclosure.

FIG. 10 is a view illustrating the configuration of a control parameter acquisition program operated on a control device of the substrate processing apparatus suitably used in an embodiment of the present disclosure.

FIG. 11 is a graph used to explain the equation (3).

FIG. 12 is a graph used to explain the equation (4).

FIG. 13 is a flow chart illustrating a control parameter acquisition process executed by an acquisition program.

FIG. 14 is a flow chart illustrating one example of the operation of a measurement process.

FIG. 15 is a flow chart illustrating one example of the operation of a verification process.

FIG. 16A is a table illustrating one example of a measurement result in a specific example of a control parameter acquisition process by the substrate processing apparatus according to an embodiment of the present disclosure, showing a value of temperature uniformity in the plane of a substrate and an average temperature for each power ratio value for a control lower limit temperature value in Step 100.

FIG. 16B is a table illustrating one example of a measurement result in a specific example of a control parameter acquisition process by the substrate processing apparatus according to an embodiment of the present disclosure, showing a value of temperature uniformity in the plane of a substrate and an average temperature for each power ratio value for a control upper limit temperature value in Step 100.

FIG. 16C is a table illustrating a measurement result when a verification process of Step 100 is performed after calculating a control parameter in Step 106 based on the measurement results of FIGS. 16A and 16B.

### DETAILED DESCRIPTION

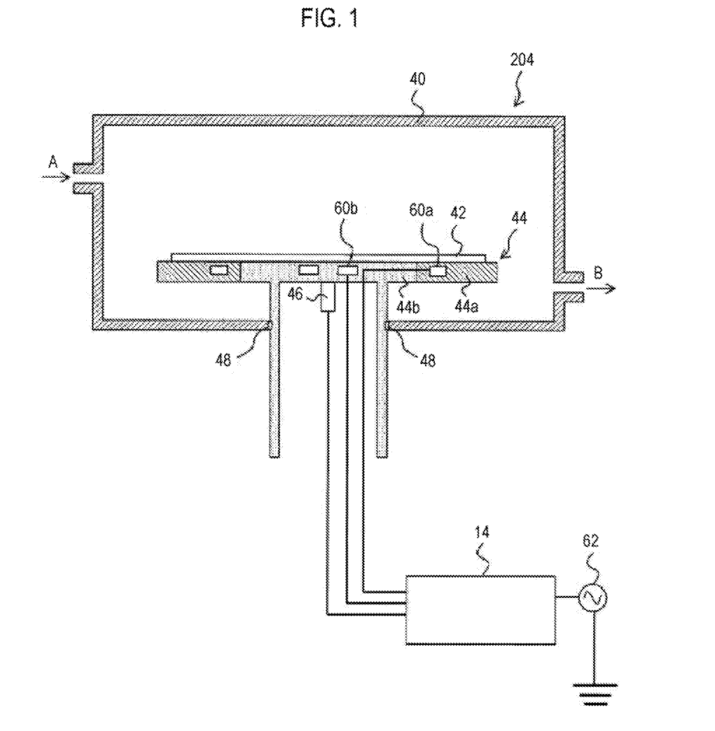

A substrate processing apparatus to which the present disclosure can be suitably applied will be described in brief with reference to FIGS. 1 to 3. As illustrated in FIG. 1, a processing furnace 204 includes a vacuum container 40 in which a substrate (semiconductor wafer) 42 to be processed is accommodated, a substrate heating mechanism 44 which heats the substrate 42 in the vacuum container 40, and a temperature detector 46 which detects the temperature of the substrate heating mechanism 44. The substrate heating mechanism 44 is inserted and fixed in a hole formed in one side (e.g., the bottom) of the vacuum container 40 with a space between the substrate heating mechanism 44 and the vacuum container 40 blocked by a seal member 48.

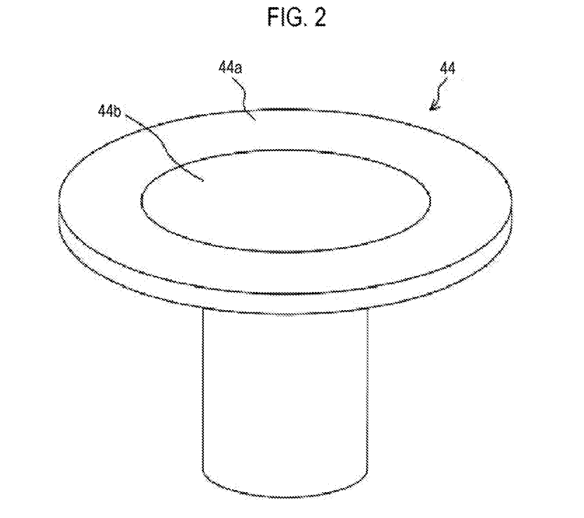

The substrate heating mechanism 44 has a combined disc/cylindrical shape, as illustrated in FIGS. 1 and 2. The upper side (disc portion) of the substrate heating mechanism 44 is substantially concentrically divided into a first region 44a and a second region 44b.

The substrate heating mechanism 44 includes a first heating part 60a for heating in the first region 44a (i.e., the outer region) of the substrate heating mechanism 44 and a second heating part 60b for heating in the second region 44b (i.e., the inner region) of the substrate heating mechanism 44. Here, each of the first heating part and the second heating part includes a heater and a heater electrode to which power is supplied from a power supply 62 via a power regulator. The temperature detector 46 is connected to the second region 44b in the cylinder of the substrate heating mechanism 44 and outputs a detected temperature to a control device 14.

As illustrated in FIG. 1, the first heating part 60a including the heater and the heater electrode is installed in the first region 44a of the substrate heating mechanism 44. Similarly, the second heating part 60b is installed in the second region 44b. The first heating part 60a and the second heating part 60b are connected to the control device 14. Therefore, the first heating part 60a and the second heating part 60b receive predetermined power from the control device 14 and heats the heater with the received power to control the temperature of a corresponding region of the substrate heating mechanism 44.

As indicated by arrows A and B in the figure, an exhaust port is installed in the vacuum container 40. Therefore, the interior of the vacuum container 40 is made into a vacuum atmosphere by an exhaust means (not shown). When the interior of the vacuum container 40 is in the vacuum atmosphere, a gas introduced into the vacuum container 40 by a gas supply means (not shown) and the interior of the vacuum container 40 is adjusted to a pressure for film formation by a pressure adjustment means (not shown). When the internal pressure of the vacuum container 40 is adjusted, a temperature and a power ratio value are set, power is supplied to the substrate heating mechanism 44 based on the set temperature and the set power ratio value, and the substrate 42 is heated by the substrate heating mechanism 44. Hereinafter, the set temperature and the set power ratio value may be sometimes referred to as control parameters. The power ratio value refers to a ratio of power supplied to the second heating part 60b to power supplied to the first heating part 60a. In the specification, description will be given on the basis of the power supplied to the second heating part 60b.

When the temperature of the substrate 42 is stabilized, the temperature is measured and the temperature uniformity of the substrate is calculated. An operator determines whether or not the calculated temperature uniformity is appropriate. If it is determined that the temperature uniformity is appropriate, a power ratio value at that time is used to perform the subsequent substrate processing. That is, a semiconductor with this power ratio value set as a temperature parameter in manufacturing a semiconductor product is manufactured. In contrast, if it is determined that the temperature uniformity is not appropriate, the power ratio value is changed and the measurement is again performed.

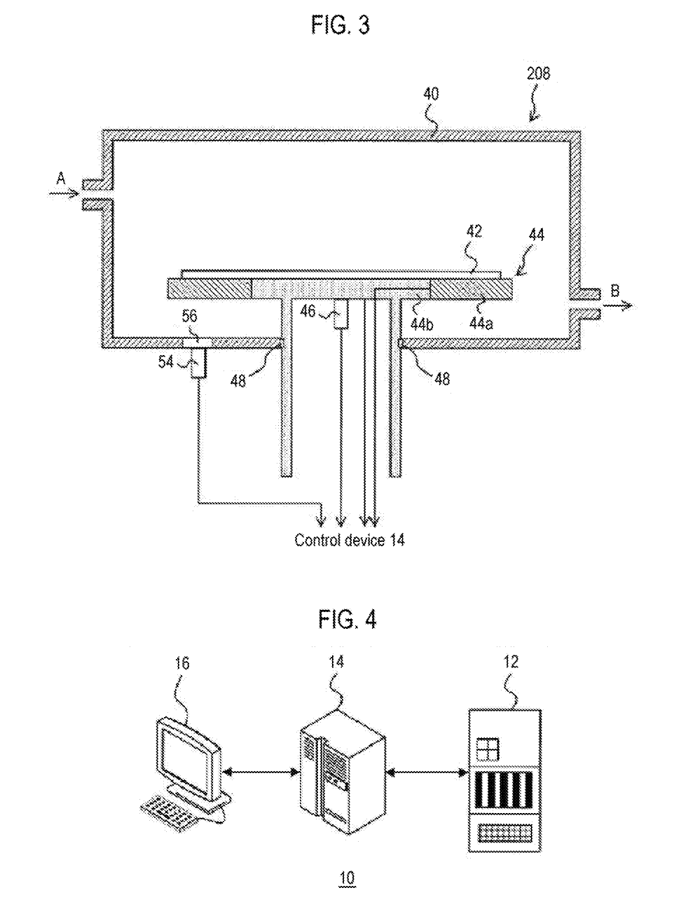

A processing furnace 208 with a changed configuration of temperature detection will now be described. FIG. 3 is a view illustrating a processing furnace 208 of the substrate processing apparatus. In FIG. 3, substantially the same elements and portions as FIG. 1 are denoted by the same reference numerals. A method of calculating a control factor (optimal temperature ratio value) of this embodiment to be described later will be applied to the processing furnace 208 of FIG. 3.

However, as illustrated in FIG. 3, the processing furnace 208 includes a third temperature detector 54 for detecting infrared and far-infrared electromagnetic waves in the air atmosphere outside of the vacuum container 40 and measuring a temperature. The processing furnace 208 performs temperature measurement by means of the third temperature detector 54 during substrate processing. The third temperature detector 54 measures the temperature of the first region 44a of the substrate heating mechanism 44 through a transparent window 56 made of a material with high transparency, such as quartz. Therefore, the temperature uniformity is calculated based on the temperatures detected by the first temperature detector 46 and the third temperature detector 54. However, in such a temperature measuring method, by-products having no contribution to film formation may adhere to the vacuum side surface of the transparent window 56 every time the film forming process is repeated, thereby reducing the transparency, which may result in difficulty in accurate temperature measurement.

When the substrate heating mechanism 44 is divided into a plurality of heating control regions in this way, it is common that a temperature detector is connected to one heating control region not affected by plasma and a corrosive gas, a calculation process is performed by a control device based on a temperature detected by the temperature detector, and power to be supplied is controlled based on a result of the calculation process, thereby achieving temperature control with high reliability and reproducibility.

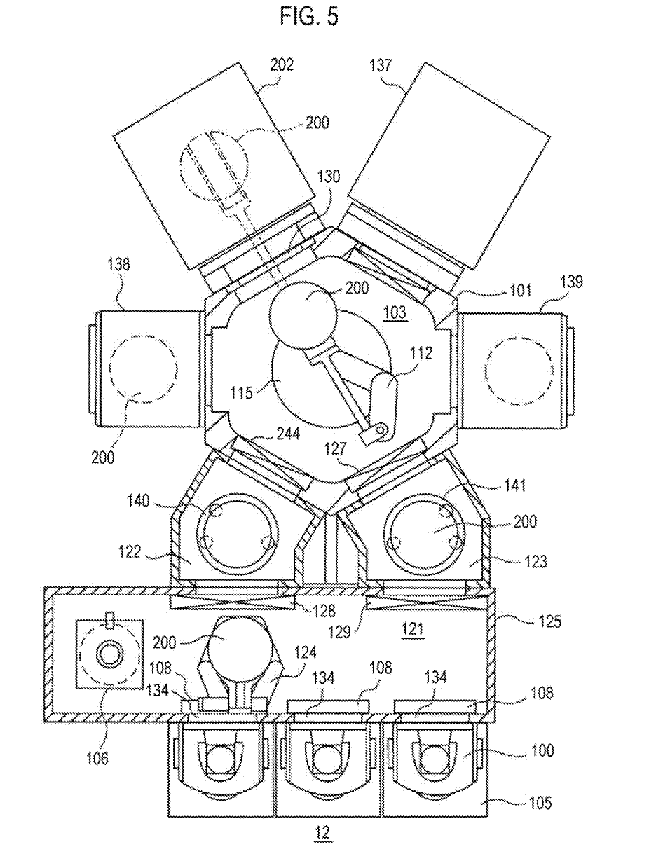

Next, a substrate processing apparatus 10 according to an embodiment of the present disclosure will be described. As illustrated in FIG. 4, the substrate processing apparatus 10 includes a substrate processing apparatus main body 12, a control device 14 for controlling substrate processing of the substrate processing apparatus main body 12, and a display/input device 16 forming an interface between the control device 14 and an operator. These components of the substrate processing apparatus 10 are used to heat at least two regions of a substrate by supplying power based on a predetermined power ratio to the at least two regions, calculate the temperature uniformity in the plane of the substrate heated based on the supplied power, store a power ratio value calculated based on the calculated temperature uniformity, and controls power to be supplied, based on the stored power ratio value. In addition, these components of the substrate processing apparatus 10 may be either integrated in the same housing or separately contained in different housings.

The display/input device 16 is used to allow the operator to perform manipulations required for the substrate processing apparatus main body 12. Upon receiving a manipulation from the operator, the display/input device 16 outputs data or information related to the manipulation to the control device 14. In addition, the display/input device 16 displays predetermined information produced by control of the control device 14 on a display or the like.

The control device 14 controls power to be supplied to the substrate heating mechanism 44 of the substrate processing apparatus main body 12, based on a power ratio value. In addition, the control device 14 receives a temperature detected and output by the substrate processing apparatus main body 12 and calculates the temperature uniformity based on the received temperature. The control device 14 calculates an optimal power ratio value (in the specification, sometimes referred to as a control factor) based on the calculated temperature uniformity. Further, based on the optimal power ratio value (control factor) calculated for a predetermined target temperature, the control device 14 controls the temperature of the substrate processing apparatus main body 12 by controlling the power to be supplied. A process of calculating the optimal power ratio value (control factor) by the control device 14 will be described later.

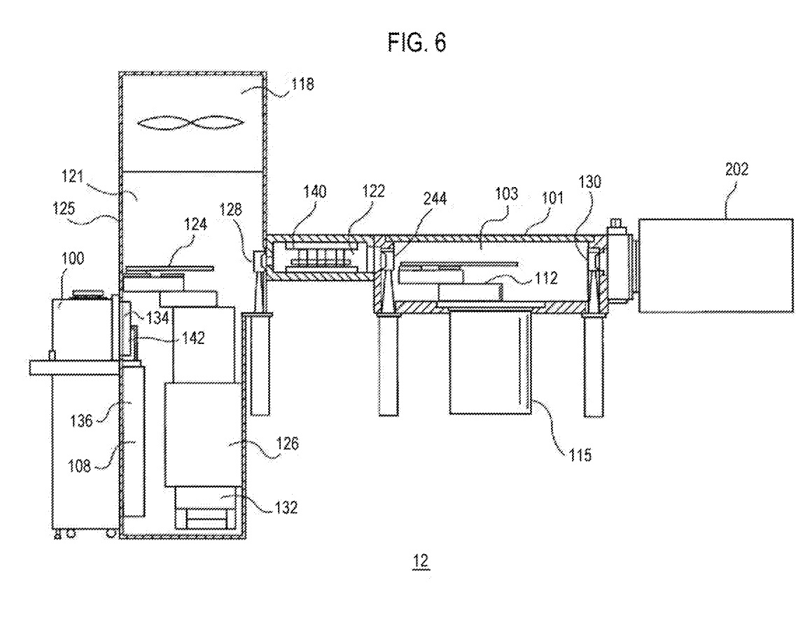

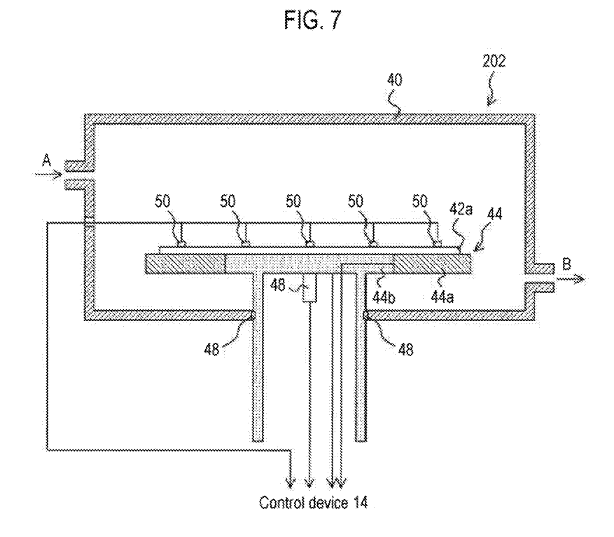

The substrate processing apparatus main body 12 is configured to form a film having a desired thickness on the substrate 42 and make the film thickness uniform. The substrate processing apparatus main body 12 will be described in detail with reference to FIGS. 5 and 6. A lower side of FIG. 5 and a left side of FIG. 6 correspond to the front side of the substrate processing apparatus main body 12. The substrate processing apparatus main body 12 uses a front opening unified pod (FOUP) as a carrier for transferring the substrate 42 such as a wafer.

As illustrated in FIGS. 5 and 6, the substrate processing apparatus main body 12 includes a first transfer chamber 103 having a load lock chamber to withstand a pressure (negative pressure) less than the atmospheric pressure, such as a vacuum. A housing 101 of the first transfer chamber 103 is formed in a hexagonal box shape with both upper and lower ends blocked when viewed from top. A first wafer transfer device 112 to transfer a substrate 200 under the negative pressure is installed in the first transfer chamber 103. The first wafer transfer device 112 is configured to be lifted up/down by an elevator 115 while maintaining the airtightness of the first transfer chamber 103.

A pre-chamber 122 for loading and a pre-chamber 123 for unloading are connected to two side walls, which are located in the front, of six side walls of the housing 101, via gate valves 244 and 127, respectively, and have a load lock chamber structure capable of withstanding a negative pressure. Further, a substrate mounting table 140 for loading is installed in the pre-chamber 122 and a substrate mounting table 141 for unloading is installed in the pre-chamber 123.

A second transfer chamber 121 used substantially under the atmospheric pressure is connected to the front side of the pre-chamber 122 and pre-chamber 123 via gate valves 128 and 129. A second wafer transfer device 124 to transfer the substrate 200 is installed in the second transfer chamber 121. The second wafer transfer device 124 is configured to be lifted up/down by an elevator 126 installed in the second transfer chamber 121 and is also configured to be horizontally reciprocated by a linear actuator 132.

As illustrated in FIG. 5, an orientation flat aligning device 106 is installed in the left side of the second transfer chamber 121. In addition, as illustrated in FIG. 6, a cleaning unit 118 to supply clean air is installed in the upper side of the second transfer chamber 121.

As illustrated in FIGS. 5 and 6, a wafer loading/unloading port 134 for loading/unloading the substrate 200 to/from the second transfer chamber 121, a lid 142 for closing the wafer loading/unloading port 134, and a pod opener 108 are installed in a housing of the second transfer chamber 121. The pod opener 108 has a cap opening/closing mechanism 136 for opening/closing the lid 142 for closing caps of pods 100 mounted on an I/O stage 105 and the wafer loading/unloading port 134. In addition, the pod opener 108 allows the pods 100 to load/unload substrates by using the cap opening/closing mechanism 136 to open/close the lid 142 for closing the caps of the pods 100 mounted on the I/O stage 105 and the wafer loading/unloading port 134. In addition, the pods 100 are supplied to and discharged from the I/O stage 105 by means of an intra-process transfer device (or a rail guided vehicle (RGV)) (not shown).

As illustrated in FIG. 5, a first processing furnace 202 and a second processing furnace 137 for subjecting the substrate to a desired process are respectively connected adjacent to two side walls, which are located in the rear, of the six side walls of the housing 101. Both of the first processing furnace 202 and the second processing furnace 137 are configured as cold wall type processing furnaces. A first cooling unit 138 as a third processing furnace and a second cooling unit 139 as a fourth processing furnace are respectively connected to the two remaining opposing side walls of the six side walls of the housing 101. Both of the first cooling unit 138 and the second cooling unit 139 are configured to cool a processed substrate 200.

Hereinafter, a substrate processing process using the substrate processing apparatus 10 as configured above will be described with reference to FIGS. 5 and 6. A pod 100 in which 25 unprocessed substrates 200 are accommodated is transferred to the substrate processing apparatus main body 12 by an intra-process transfer device. As illustrated in FIGS. 5 and 6, the transferred pod 100 is passed over from the intra-process transfer device to the I/O stage 105 and is mounted on the I/O stage 105. The lid 142 for opening/closing the cap of the pod 100 and the wafer loading/unloading port 134 is removed by the cap opening/closing mechanism 136 and a wafer entrance of the pod 100 is opened.

When the pod 100 is opened by the pod opener 108, the second wafer transfer device 124 installed in the second transfer chamber 121 picks up a substrate 200 from the pod 100, carries the substrate 200 into the pre-chamber 122, and transfers the substrate 200 onto the substrate mounting table 140. During this transferring operation, the gate valve 244 of the first transfer chamber 103 is closed to maintain a negative pressure of the first transfer chamber 103. When the substrate 200 is completed to be transferred onto the substrate mourning table 140, the gate valve 128 is closed and the pre-chamber 122 is exhausted to a negative pressure by an exhauster (not shown).

When the pre-chamber 122 is decompressed to a preset pressure value, the gate valves 244 and 130 are opened to communicate the pre-chamber 122, the first transfer chamber 103 and the first processing furnace 202 with each other. Subsequently, the first wafer transfer device 112 of the first transfer chamber 103 picks up the substrate 200 from the substrate mounting table 140 and carries the substrate 200 into the first processing furnace 202. Then, a processing gas is supplied into the first processing furnace 202 to subject the substrate 200 to a desired process. A control parameter obtained by an acquisition program is used for temperature control in the corresponding process.

When the above-mentioned process is completed in the first processing furnace 202, the processed substrate 200 is carried into the first transfer chamber 103 by the first wafer transfer device 112 of the first transfer chamber 103. Then, the first wafer transfer device 112 carries the substrate 200, which was carried from the first processing furnace 202, into the first cooling unit 138 to cool the processed substrate 200.

When the substrate 200 is transferred into the first cooling unit 138, the first wafer transfer device 112 transfers a substrate 200 prepared on the substrate mounting table 140 of the pre-chamber 122 into the first processing furnace 202 according to the above-described operation and a processing gas is supplied into the first processing furnace 202 to subject the substrate 200 to a desired process. When a preset cooling time elapses in the first cooling unit 138, the cooled substrate 200 is carried from the first cooling unit 138 into the first transfer chamber 103 by first wafer transfer device 112.

After the cooled substrate 200 is carried from the first cooling unit 138 into the first transfer chamber 103, the gate valve 127 is opened. Then, the first wafer transfer device 112 transfers the substrate 200, which was carried from the first cooling unit 138, into the pre-chamber 123 and transfers the substrate 200 onto the substrate mounting tables 141. Thereafter, the pre-chamber 123 is closed by the gate valve 127.

When the pre-chamber 123 is closed by the gate valve 127, the interior of the pre-chamber 123 for unloading returns to substantially the atmospheric pressure by an inert gas. When the interior of the pre-chamber 123 returns to substantially the atmospheric pressure, the gate valve 129 is opened and the lid 142 for closing the wafer loading/unloading port 134 corresponding to the pre-chamber 123 of the second transfer chamber 121 and the cap of an empty pod 100 mounted on the I/O stage 105 are opened by the pod opener 108.

Subsequently, the second wafer transfer device 124 of the second transfer chamber 121 picks up the substrate 200 from the substrate mounting table 141, carries the substrate 200 into the second transfer chamber 121 and accommodates the substrate 200 in the pod 100 through the wafer loading/unloading port 134 of the second transfer chamber 121. When the accommodation of the 25 processed substrates 200 in the pod 100 is completed, the lid 142 for closing the cap of the pod 100 and the wafer loading/unloading port 134 is closed by the pod opener 108. The closed pod 100 is transferred from the I/O stage 105 to the next process by the intra-process transfer device.

When the above-described operation is repeated, the substrates are sequentially processed. In addition, although a case of using the first processing furnace 202 and the first cooling unit 138 has been described by way of an example, the same operation is applied to a case of the second processing furnace 137 and the first cooling unit 139.

In addition, although the above-described substrate processing apparatus uses the pre-chamber 122 for loading and the pre-chamber 123 for unloading, the pre-chamber 123 may be used for loading and the pre-chamber 122 may be used for unloading. In addition, the first processing furnace 202 and the second processing furnace 137 may be used to perform the same process or different processes. When the first processing furnace 202 and the second processing furnace 137 are used for different processes, for example, a process for the substrate 200 may be performed in the first processing furnace 202 and then a different process may be performed in the second processing furnace 137. In addition, when a process for the substrate 200 is performed in the first processing furnace 202 and then a different process is performed in the second processing furnace 137, the first cooling unit 138 (or the second cooling unit 139) may be intermediated between these processes.

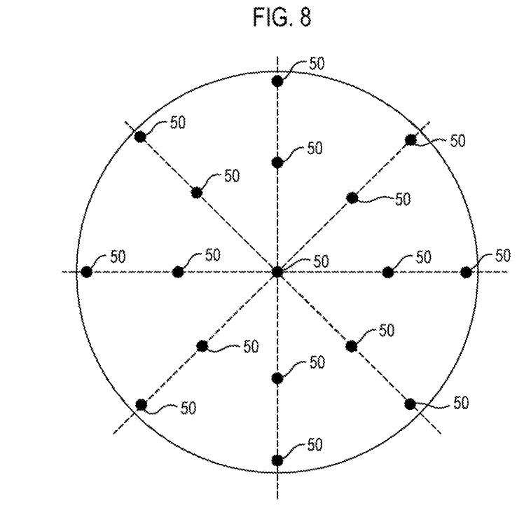

As illustrated in FIG. 7, in the substrate processing apparatus 10 according to the embodiment of the present disclosure, a substrate 42a to which a plurality of temperature detectors 50 for detecting the temperature of the substrate is connected is mounted on the substrate heating mechanism 44. Each temperature detector 50 outputs a detected temperature to the control device 14. Therefore, the plurality of temperature detectors 50 detects temperatures at plural spots of the substrate 42a and outputs the detected temperatures to the control device 14. The temperature uniformity of the substrate is calculated from the temperatures detected by the plurality of temperature detectors 50. In FIG. 7, substantially the same elements and portions as FIG. 1 are denoted by the same reference numerals.

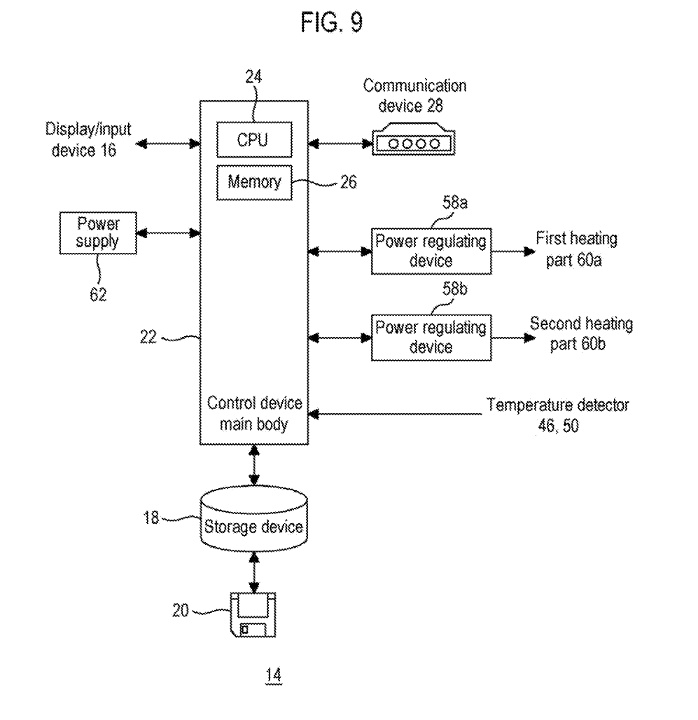

FIG. 8 is a plan view illustrating an example of arrangement of temperature detectors 50 connected to the substrate 42a. It may be desirable to arrange the temperature detectors 50 in the plane of the substrate 42a evenly in terms of area. It may also be desirable to set the number of connected temperature detectors 50 according to the area of the substrate 42a and the processing capability of the control device 14. Although 17 temperature detectors 50 are connected in the example shown in FIG. 8, the number of connected temperature detectors 50 is not limited thereto.

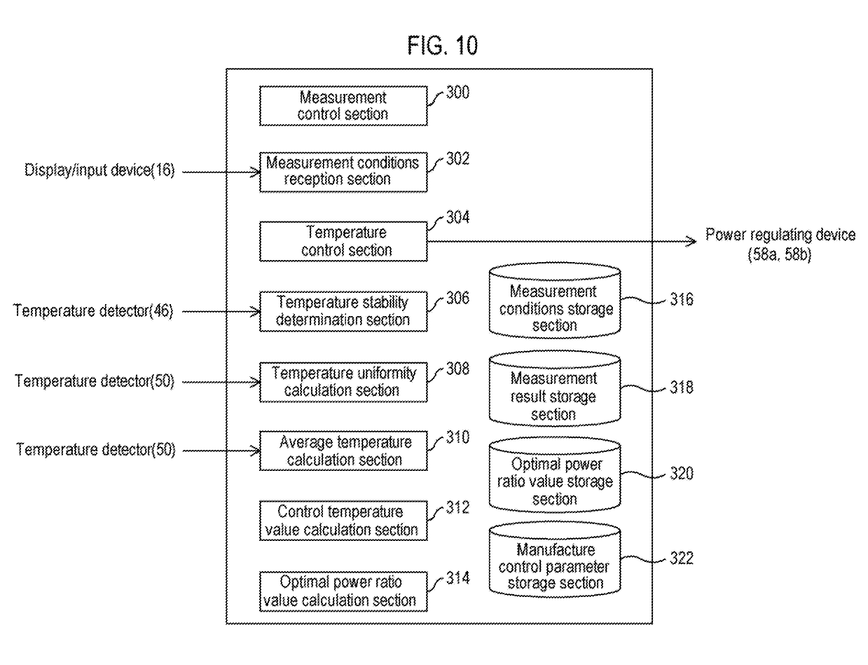

Next, the control device 14 of the substrate processing apparatus 10 according to the embodiment of the present disclosure will be described. As illustrated in FIG. 9, the control device 14 is connected with a power supply 62 and includes a control device main body 22 including a CPU 24 as a control part, a memory 26 as a first storage part, and the like, a communication device 28, a storage device 18 as a second storage part such as a hard disk drive or the like, and power regulating devices 58a and 58b. The CPU 24 executes a program (which will be described later) loaded into the memory 26 and performs control of the substrate processing apparatus main body 12. The memory 26 stores the program executed by the CPU 24 and information stored in the storage device 18. The communication device 28 conducts data exchange with the substrate processing apparatus main body 12 and an external computer via a network (not shown).

The power regulating devices 58a and 58b are respectively connected to the first heating part 60a and second heating part 60b of the substrate heating mechanism 44. The power regulating devices 58a and 58b are controlled by the CPU 24 and supply power to the substrate heating mechanism 44. In this example, the power supplied by the power regulating devices 58a and 58b is based on a predetermined power ratio as will be described later. Further, the control device 14 receives temperatures detected by the temperature detectors 46 and 50. In this way, the control device 14 includes components of the general computer. In addition, the program may be supplied through the communication device 28 or may be supplied through a recording medium 20 such as FD, CD, DVD or the like.

Next, a method for acquiring an optimal power ratio value (control factor) which is one of several important control parameters used for heating control of the substrate processing apparatus 10 according to the embodiment of the present disclosure will be described.

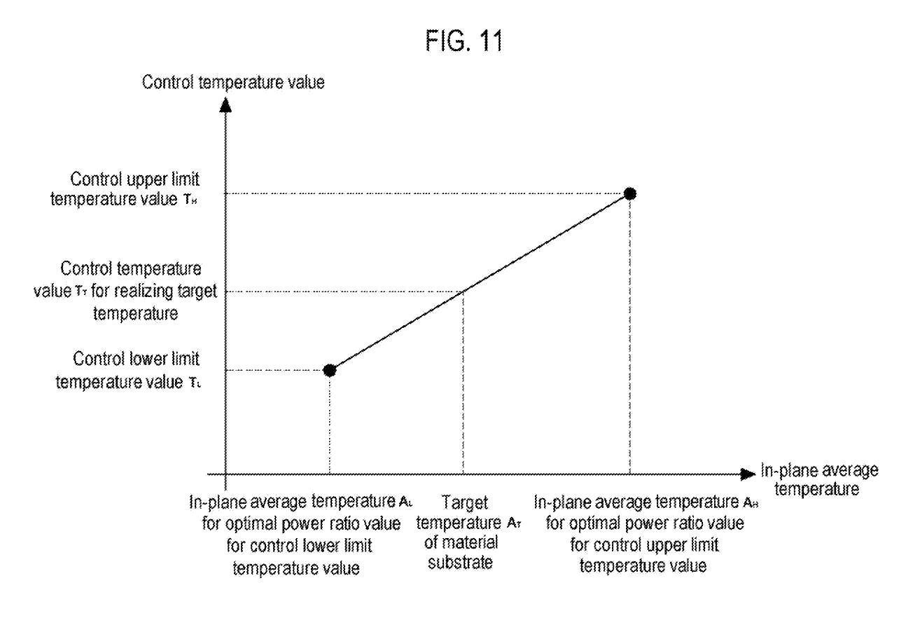

As illustrated in FIG. 10, a control parameter acquisition program (hereinafter simply referred to as an acquisition program) 30 includes a measurement control section 300, a measurement conditions reception section 302, a temperature control section 304, a temperature stability determination section 306, a temperature uniformity calculation section 308, an average temperature calculation section 310, a control temperature value calculation section 312, an optimal power ratio value calculation section 314, a measurement conditions storage section 316, a measurement result storage section 318, an optimal power ratio value storage section 320 and a manufacture control parameter storage section 322. The acquisition program 30 is supplied to the control device 14 via the communication device 28 or the recording medium 20, loaded into the memory 26 and executed by the CPU 24 on an OS (not shown).

When the heating control is performed to set the substrate to a target temperature, a temperature value and a power ratio value are set as control parameters. Hereinafter, a temperature value set as a control parameter will be referred to as a control temperature value. Since the target temperature of the substrate is different from the control temperature value, there is a need to set control parameters (the control temperature value and the power ratio value) suitable for the target temperature.

In the acquisition program 30, control parameters suitable for this target temperature are acquired. More specifically, first, a temperature is measured when the heating control is performed with a first control temperature value set as predetermined temperature conditions. At this time, measurement is repeatedly conducted while changing the power ratio value. A power ratio value providing the best temperature uniformity, an average temperature calculated from measured temperatures, and the first control temperature value are conserved in association. Nest, a temperature is measured when the heating control is performed with a second control temperature value set as predetermined temperature conditions. Similarly, measurement is repeatedly conducted while changing the power ratio value. Then, a power ratio value providing the best temperature uniformity, an average temperature calculated from measured temperatures, and the second control temperature value are conserved in association. Control parameters are obtained by calculating a control temperature value and a power ratio value for realizing a desired target temperature based on the conserved information.

In addition, as will be described later, the acquisition program 30 has a function of verifying a power ratio value providing the best temperature uniformity for the first control temperature value or the second control temperature value, or a calculated power ratio value. A process of verifying the power ratio value is a process of acquiring a true power ratio value, with a power ratio value to be verified, as a provisional power ratio value. In the process of verifying the power ratio value, specifically, the heating and temperature measurement is repeated using a plurality of power ratio values, which are close to the provisional power ratio value (the power ratio value to be verified), as control parameters. Then, a power ratio value providing the best temperature uniformity is acquired as an optimal power ratio value (control factor).

The measurement control section 300 controls the repetition of measurement while setting control parameters.

The measurement conditions reception section 302 receives measurement conditions input from the operator through the display/input device 16. The measurement conditions reception section 302 outputs the received measurement conditions to the measurement conditions storage section 316. In this example, the measurement conditions include predetermined temperature conditions (a control lower limit temperature value and a control upper limit temperature value), a measurement start power ratio value, a measurement interval, a measurement number, a verification interval and a verification number. In addition, the measurement conditions reception section 302 may receive measurement conditions from an external computer or the like via the communication device 28.

The control lower limit temperature value is a lower limit value which can be set as a control temperature value and corresponds to the above-mentioned first control temperature value. Although in this embodiment the lower limit value is used as the first control temperature value in this way, the first control temperature value is not limited to the lower limit value as long as it can be set as the control temperature value.

The control upper limit temperature value is an upper limit value which can be set as a control temperature value and corresponds to the above-mentioned second control temperature value. Although in this embodiment the upper limit value is used as the second control temperature value in this way, the second control temperature value is not limited to the upper limit value as long as it can be set as the control temperature value and is higher than the first control temperature value.

The measurement start power ratio value is a power ratio value set before measurement.

The measurement interval is a value indicating whether to use a power ratio value, which is changed by some extent from a power ratio value in the current measurement, in the next measurement, when the measurement is repeated while changing the power ratio value.

The measurement number is a value indicating the number of times of repetition (the number of times of measurement) when the measurement is repeated while changing the power ratio value.

The verification interval and the verification number are values used to verify a power ratio value providing the best temperature uniformity for the first control temperature value or the second control temperature value, or a calculated power ratio value. The verification interval is a value indicating whether to use a power ratio value, which is changed by some extent from a power ratio value in the current measurement, in the next measurement, when the measurement is repeated in the verification process. The verification number is a value indicating the number of times of repetition when the measurement is repeated in the verification process.

The temperature control section 304 controls the power regulating devices 58a and 58b based on the control parameters (the control temperature value and the power ratio value) set by the measurement control section 100. More specifically, the temperature control section 304 controls the power regulating device 58a to supply predetermined power to the first heating part 60a of the substrate heating mechanism 44 and controls the power regulating device 58b to supply power based on the corresponding power and the corresponding power ratio value to the second heating part 60b of the substrate heating mechanism 44. For example, the temperature control section 304 controls the power regulating device 58b to supply power, which is calculated by multiplying the corresponding power supplied to the first heating part 60a by the corresponding power ratio value, to the second heating part 60b.

The temperature stability determination section 306 determines whether or not the temperature by the heating is stabilized. Specifically, for example when a temperature detected by the temperature detector 46 continues to match a control temperature value for a certain period of time, it is determined that the temperature is stabilized. In this example, the certain period of time is a preset period of time, for example, about 3 minutes. However, this period of time may be varied depending on the material, composition, heater winding pattern and so on of the substrate heating mechanism.

The temperature uniformity calculation section 308 calculates an index value of the temperature uniformity in the plane of the substrate 42a. For example, the temperature uniformity calculation section 308 obtains the index value of the temperature uniformity according to the following equation.

Temperature uniformity index value[%]=(highest temperature value−lowest temperature value)/(highest temperature value−lowest temperature value)×100 (1)

In this equation, the highest temperature value and the lowest temperature value indicate the highest temperature and the lowest temperature among temperatures of a plurality of regions detected by the temperature detectors 50. In the equation (1), a smaller temperature uniformity index value indicates better temperature uniformity.

However, the temperature uniformity index value may be obtained according to calculation formula other than the equation (1). Since it is considered that a smaller difference between the highest temperature and the lowest temperature of the substrate 42a provides a smaller temperature uniformity index value, i.e., better temperature uniformity, the temperature uniformity index value may be calculated according to the following equation (2) which is a simplified form of the calculation process.

Temperature uniformity index value=highest value of temperature−lowest value of temperature (2)

The temperature uniformity calculation section 308 outputs the calculated temperature uniformity index value to the measurement result storage section 318.

The average temperature calculation section 310 calculates an average value of temperatures in the plane of the substrate 422. Specifically, the average temperature calculation section 310 calculates an average value of temperatures of a plurality of regions detected by the temperature detectors 50a to 50e. The average temperature calculation section 310 outputs the calculated temperature average value to the measurement result storage section 318.

The control temperature value calculation section 312 calculates a control temperature value for realizing a substrate target temperature. For example, the control temperature value calculation section 312 calculates a control temperature value T_{T} for realizing the target temperature based on the following equation (3).

$${T}_{T} = \frac{{A}_{T} - {A}_{L}}{{A}_{H} - {A}_{L}} \times ( {T}_{H} - {T}_{L} ) + {T}_{L} \qquad ( 3 )$$

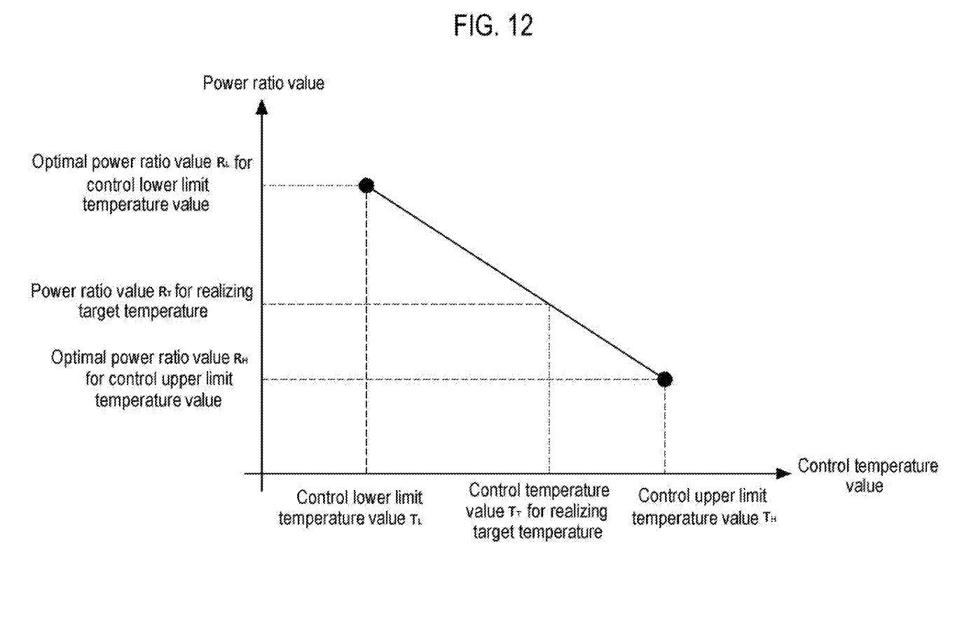

In the above equation (3), A_{T} represents a target temperature, A_{L} represents an average temperature for conditions of best temperature uniformity when measurement is repeated while changing a power ratio value for the first control temperature value (here, the control lower limit temperature value), A_{H} represents an average temperature for conditions of best temperature uniformity when measurement is repeated while changing a power ratio value for the second control temperature value (here, the control upper limit temperature value), T_{L} represents the first control temperature value (here, the control lower limit temperature value), and T_{H} represents the second control temperature value (here, the control upper limit temperature value). The above equation (3) is depicted as a graph in FIG. 11.

The optimal power ratio value calculation section 314 calculates a power ratio value for realizing the target temperature based on the control temperature value for realizing the target temperature calculated by the control temperature value calculation section 312. For example, the optimal power ratio value calculation section 314 calculates a power ratio value R_{T} for realizing the target temperature based on the following equation (4).

$${R}_{T} = \frac{{T}_{T} - {T}_{L}}{{T}_{H} - {T}_{L}} \times ( {R}_{H} - {R}_{L} ) + {R}_{L} \qquad ( 4 )$$

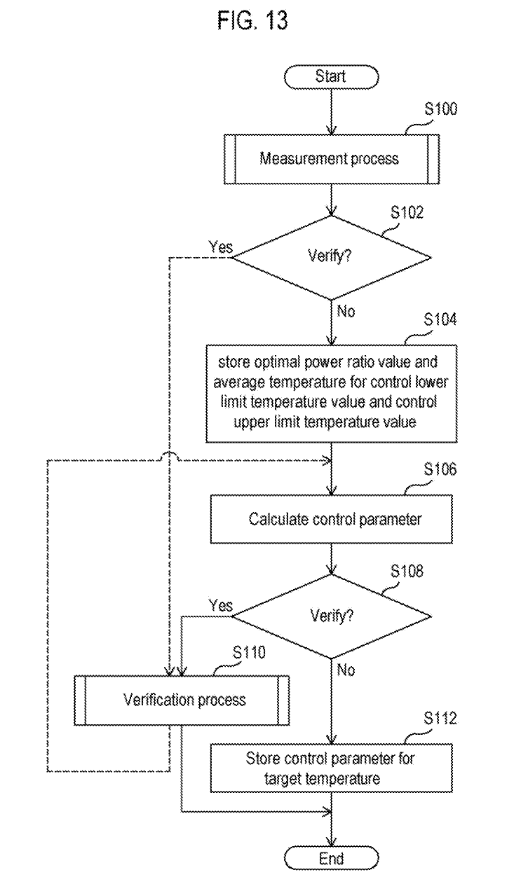

In the above equation (4), represents the control temperature value calculated by the control temperature value calculation section 312, T_{H} and T_{L} are the same as mentioned above, R_{L} represents a power ratio value for conditions of best temperature uniformity when measurement is repeated while changing a power ratio value for the first control temperature value (here, the control lower limit temperature value), and R_{H} represents a power ratio value for conditions of best temperature uniformity when measurement is repeated while changing a power ratio value for the second control temperature value (here, the control upper limit temperature value). In the following description, a power ratio value for conditions of best temperature uniformity when heating and measurement are repeated while changing a power ratio value for any control temperature value will be referred to as an optimal power ratio value. The above equation (4) is depicted as a graph in FIG. 12.

According to the above equations (3) and (4), during semiconductor fabrication, when it is desired to heat a material substrate such that the temperature of the material substrate becomes A_{T}, it is possible to realize good temperature uniformity and a target substrate temperature by using R_{T} and T_{T} as control parameters to control the heating.

The measurement conditions storage section 316 stores the measurement conditions output by the measurement conditions reception section 302. The measurement result storage section 318 stores the values calculated by the temperature uniformity calculation section 308 and the average temperature calculation section 310 in association with control parameters. The optimal power ratio value storage section 320 stores the optimal power ratio value for the first control temperature value in association with the average value of temperatures in the plane of the substrate 42 when the substrate 42 is heated with the optimal power ratio value. The manufacture control parameter storage section 322 stores the target temperature of the material substrate, the control temperature value and the power ratio value for realizing the target temperature, in association with each other. The above-mentioned storage sections stores values, for example using the storage device 18.

Next, a flow of a control parameter acquisition process by the substrate processing apparatus 10 according to the embodiment of the present disclosure will be described.

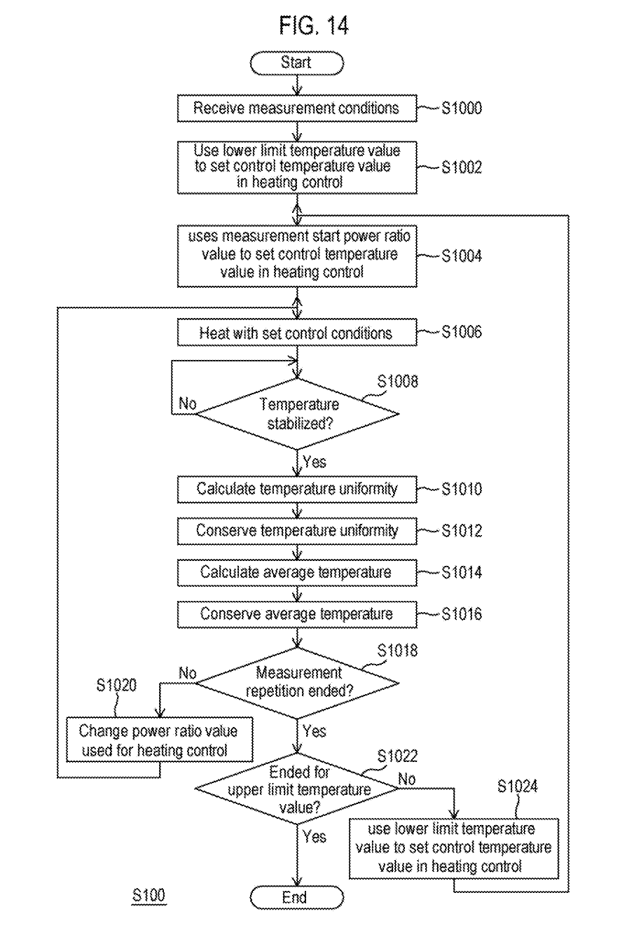

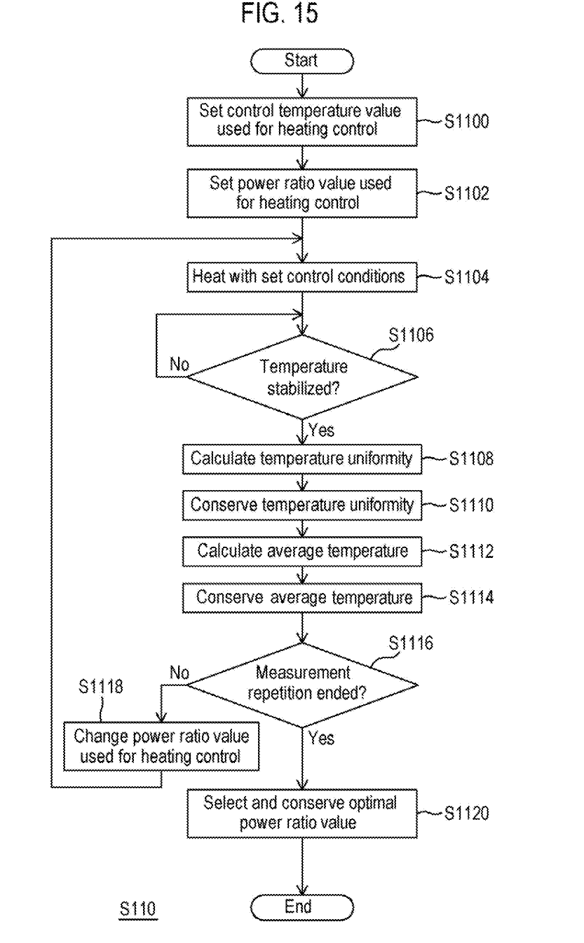

As illustrated in FIG. 13, first, at Step 100 (S100), a measurement process is performed. In this process, a plurality of power ratio values for the first control temperature value as predetermined temperature conditions is set and heating and temperature detection are performed. Thereafter, a plurality of power ratio values for the second control temperature value as predetermined temperature conditions is set and heating and temperature detection are performed. Details of Step 100 will be described with reference to FIG. 14.

After Step 100, at Step 102 (S102), the measurement control section 300 determines whether or not it is instructed to verify a result obtained in Step 100. For example, an instruction on whether to verify the result may be input from the display/input device 16 or may be preset. If it is not instructed to verify the result, the process proceeds to Step 104. If it is instructed to verify the result, the process proceeds to Step 110.

At Step 104 (S104), the measurement control section 300 stores the first control temperature value (here, the control lower limit temperature value), the optimal power ratio value for the first control temperature value, and the average value of measurements in the plane of the substrate 42a when the substrate 42a is heated with the first control temperature value and the optimal power ratio value, among the measurement results in Step 100 stored in the measurement result storage section 318, in the optimal power ratio value storage section 320 in association with each other. In addition, the measurement control section 300 stores the second control temperature value (here, the control upper limit temperature value), the optimal power ratio value for the second control temperature value, and the average value of measurements in the plane of the substrate 42a when the substrate 42a is heated with the second control temperature value and the optimal power ratio value, among the measurement results in Step 100 stored in the measurement result storage section 318, in the optimal power ratio value storage section 320 in association with each other.

After Step 104, at Step 106 (S106), the control temperature value calculation section 312 and the optimal power ratio value calculation section 314 calculate control parameters (a control temperature value and a power ratio value) for realizing the target temperature of the material substrate. Specifically, the control temperature value calculation section 312 calculates a control temperature value for realizing the target temperature according to the above equation (3) based on the information stored in the optimal power ratio value storage section 320 and the optimal power ratio value calculation section 314 calculates a power ratio value for realizing the target temperature according to the above equation (4) based on the information stored in the optimal power ratio value storage section 320 and the control temperature calculated by the control temperature value calculation section 312.

The target temperature may be provided to the control temperature value calculation section 312 and the optimal power ratio value calculation section 314 before Step 106 and input from the display/input device 16 or the like. Alternatively, a pre-stored target temperature may be read out.

After Step 106, at Step 108 (S108), the measurement control section 300 determines whether or not it is instructed to verify the result obtained in Step 106. For example, an instruction on whether to verify the result may be input from the display/input device 16 or may be preset. If it is instructed to verify the result, the process proceeds to Step 110. If it is not instructed to verify the result, the process proceeds to Step 112.

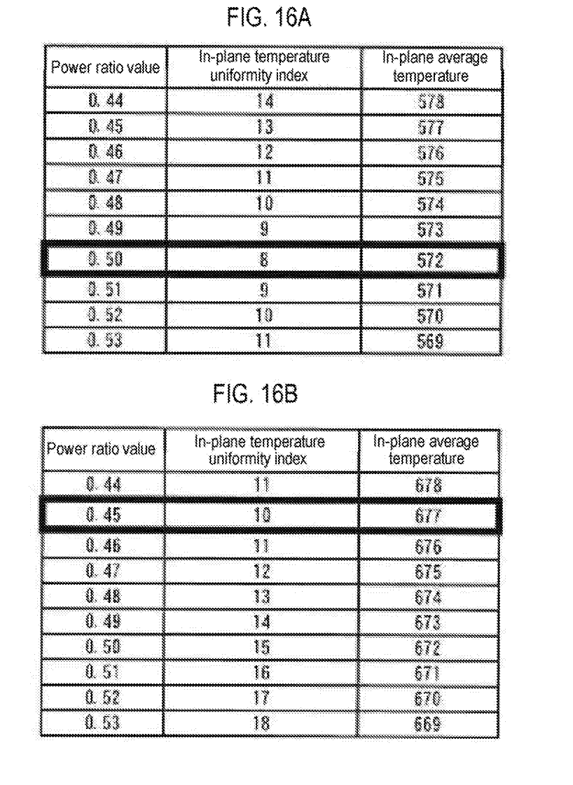

At Step 110 (S110), a process of verifying a power ratio value is performed. Specifically, if Yes in Step 102, a verification process is performed to verify whether or not there are any power ratio values more suitable than the optimal power ratio value for the first control temperature value and the optimal power ratio value for the second control temperature value. In addition, if Yes in Step 108, a verification process is performed to verify whether or not there are any power ratio values more suitable than the optimal power ratio value calculated in Step 106. Details of Step 110 will be described with reference to FIG. 15. If Yes in Step 102, after performing the verification process in Step 110, the process proceeds to Step 106. In addition, if Yes in Step 108, after performing the verification process in Step 110, the control parameter acquisition process is ended.

At Step 112 (S112), the measurement control section 300 stores the values calculated by the control temperature value calculation section 312 and the optimal power ratio value calculation section 314 in the manufacture control parameter storage section 322 in association with the target temperature.

In this way, the control parameters for realizing the target temperature are acquired. In manufacturing semiconductor products, the temperature detectors 50 and the substrate 42a are removed from the vacuum container 40, the connection of them with the control device 14 is released, and a heating process is performed with the control parameters acquired as described above.

In addition, although the verification process is performed once in the above-described flow chart, the verification process may be repeated twice or more.

Next, the details of the above-described measurement process (S100) will be described with reference to FIG. 14.

At Step 1000 (S1000), the measurement conditions reception section 302 receives measurement conditions and the measurement conditions storage section 316 stores the received measurement conditions. Specifically, the measurement conditions reception section 302 receives a control lower limit temperature value, a control upper limit temperature value, a measurement start power ratio value, a measurement interval, a measurement number, a verification interval and a verification number.

At Step 1002 (S1002), the measurement control section 300 uses the control lower limit temperature value received in Step 1000 to set a control temperature value as a control parameter in heating control.

At Step 1004 (S1004), the measurement control section 300 uses the measurement start power ratio value received in Step 1000 to set a control temperature value as a control parameter in heating control.

At Step 1006 (S1006), the temperature control section 304 controls the power regulating devices 58a and 58b to perform a heating process for the substrate 42a, based on the control parameters set in Steps 1002 and 1004.

At Step 1008 (S1008), the temperature stability determination section 306 determines whether or not the temperature by the heating is stabilized. If it is determined that the temperature is stabilized, the process proceeds to Step 1010 (S1010). If it is determined that the temperature is not stabilized, Step 1008 is repeated.

At Step 1010 (S1010), the temperature uniformity calculation section 308 calculates the temperature uniformity in the plane of the substrate 42a.

At Step 1012 (S1012), the measurement result storage section 318 stores the value of the temperature uniformity calculated in Step 1010 in association with the control parameter.

At Step 1014 (S1014), the average temperature calculation section 310 calculates an average value of temperatures in the plane of the substrate 42a.

At Step 1016 (S1016), the measurement result storage section 318 stores the temperature average value calculated in Step 1014 in association with the control parameter.

At Step 1018 (S1018), the measurement control section 300 determines whether to change the control parameter and continue the measurement. Specifically, the measurement control section 300 determines whether or not the measurement has been performed by the measurement number received in Step 1000 for the current set control temperature value. If the measurement has not been performed by the measurement number received in Step 1000, the process proceeds to Step 1020. If the measurement has been performed by the measurement number received in Step 1000, the process proceeds to Step 1022.

At Step 1020 (S1020), for a power ratio value as a control parameter in heating control, the measurement control section 300 sets a power ratio value, which is obtained by adding the measurement interval received in Step 1000 to the current set power ratio value, as a new control parameter. Then, the process returns to Step 1006.

In the meantime, at Step 1022 (S1022), the measurement control section 300 determines whether or not the measurement with the control upper limit temperature value received in Step 1000 used for the control parameter has been ended. If not ended, the process proceeds to Step 1024. If ended, the measurement process is ended.

At Step 1024 (S1024), the measurement control section 300 sets a control temperature value as a control parameter in heating control to use the control upper limit temperature value received in Step 1000. Then, the process returns to Step 1004.

As described above, a plurality of measurement results for the control lower limit temperature value and a plurality of measurement results for the control upper limit temperature value are obtained. Thereafter, a measurement result providing the best temperature uniformity is selected from the plurality of measurement results for the control lower limit temperature value and the optimal power ratio value and the corresponding average temperature are obtained. This is equally applied to the control upper limit temperature value and the optimal power ratio value and the corresponding average temperature are obtained.

Next, the details of the above-described verification process (S110) will be described. FIG. 15 is a flow chart illustrating one example of the verification process.

At Step 1100 (S1100), the measurement control section 300 sets a control temperature value as a control parameter in heating control. Specifically, when verifying an optimal power ratio value for the control lower limit temperature value or the control upper limit temperature value, the measurement control section 300 sets the control lower limit temperature value or the control upper limit temperature value to be used as a control parameter. In addition, when verifying the power ratio value calculated in the above-described Step 106, the measurement control section 300 sets the control temperature value calculated in the above-described Step 106 to be used as a control parameter.

At Step 1102 (S1102), the measurement control section 300 sets a power ratio value as a control parameter in heating control. In the verification process, it is expected to obtain a more accurate optimal power ratio value by performing measurement for power ratio values close to a power ratio value to be verified. In this embodiment, power ratio values close to a power ratio value to be verified are sequentially used as control parameters. Here, using the verification interval and the verification number received in Step 1000, measurement for the power ratio values close to the power ratio value to be verified is performed. That is, measurement for a plurality of power ratio values with different verification intervals received in Step 1000 (the total number of power ratio values corresponds to the verification number received in Step 1000) is performed. The verification interval may be equal to or shorter than the above-mentioned measurement interval.

Here, the measurement control section 300 determines a power ratio value Rstart used for initial measurement according to the following equation.

Rstart=(power ratio value to be verified)−(verification interval)×(verification number/2) (5)

In this equation (5), decimal points of as value of (verification number/2) are truncated.

In addition, when performing the verification for the optimal power ratio value for the control lower limit temperature value or the control upper limit temperature value, the power ratio value to be verified in the equation (5) is an optimal power ratio value read from the measurement result storage section 318. On the other hand, when performing the verification for the power ratio value calculated in the above-described Step 106, the power ratio value to be verified in the equation (5) is the calculated power ratio value.

At Step 1104 (S1104), the temperature control section 304 controls the power regulating devices 58a and 58b to perform a heating process for the substrate 42a, based on the control parameters set in Steps 1100 and 1102.

At Step 1106 (S1106), the temperature stability determination section 306 determines whether or not the temperature by the heating is stabilized. If it is determined that the temperature is stabilized, the process proceeds to Step 1108 (S1108). If it is determined that the temperature is not stabilized, Step 1106 is repeated.

At Step 1108 (S1108), the temperature uniformity calculation section 308 calculates the temperature uniformity in the plane of the substrate 42a.

At Step 1110 (S1110), the measurement result storage section 318 stores the value of the temperature uniformity calculated in Step 1108 in association with the control parameter.

At Step 1112 (S1112), the average temperature calculation section 310 calculates an average value of temperatures in the plane of the substrate 42a.

At Step 1114 (S1114), the measurement result storage section 318 stores the temperature average value calculated in Step 1112 in association with the control parameter.

At Step 1116 (S1116), the measurement control section 300 determines whether to change the control parameter and continue the measurement. Specifically, the measurement control section 300 determines whether or not the measurement has been performed by the measurement number received in Step 1000 for the current set control temperature value. If the measurement has not been performed by the measurement number received in Step 1000, the process proceeds to Step 1118. If the measurement has been performed by the measurement number received in Step 1000, the process proceeds to Step 1120.

At Step 1118 (S1118), for a power ratio value as a control parameter in heating control, the measurement control section 300 sets a power ratio value, which is obtained by adding the measurement interval received in Step 1000 to the current set power ratio value, as a new control parameter. Then, the process returns to Step 1104.

In the meantime, at Step 1120 (S1120), the measurement control section 300 selects an optimal power ratio value from the measurement results and outputs the selected optimal power ratio value (control factor) and the corresponding information in the optimal power ratio value storage section 320 or the manufacture control parameter storage section 322 and the optimal power ratio value storage section 320 or the manufacture control parameter storage section 322 store the optimal power ratio value and the corresponding information in association with each other.

Specifically, when verifying the optimal power ratio value for the control lower limit temperature value or the control upper limit temperature value, the measurement control section 300 selects a power ratio value corresponding to the best temperature uniformity, as an optimal power ratio value (control factor), from the results obtained in the measurement in Steps 1104 to 1118, and stores the control lower limit temperature value or the control upper limit temperature value, the selected optimal power ratio value (control factor) and an average temperature value obtained when these values are used as control parameters, in the optimal power ratio value storage section 320 in association with each other. In addition, when verifying the power ratio value calculated in the above-described Step 106, the measurement control section 300 selects a power ratio value corresponding to the best temperature uniformity, as an optimal power ratio value, from the results obtained in the measurement in Steps 1104 to 1118, and stores the control temperature value calculated in the above-described Step 105, the selected optimal power ratio value and the target temperature used in the above-described Step 106, in the manufacture control parameter storage section 322 in association with each other.

The control parameter acquisition process by the substrate processing apparatus 10 according to the embodiment of the present disclosure has been described in the above with reference to FIGS. 13 to 15. Hereinafter, a specific example will be used to supplement the above description. This specific example will be described with an operation in the order of Steps 100, 102, 104, 106 and 110 shown in FIG. 13.

In this specific example, the control lower limit temperature value is 800 degree C. and heating and measurement are performed with a power ratio value of 0.44 to 0.53 used as a control parameter for the control lower limit temperature value. In addition, in this specific example, the control upper limit temperature value is 900 degree C. and heating and measurement are performed with a power ratio value of 0.44 to 0.53 used as a control parameter for the control upper limit temperature value.

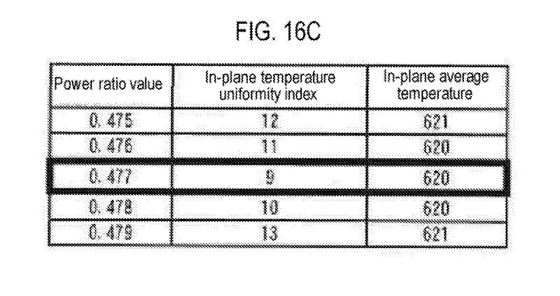

It can be seen from FIG. 16A that the power ratio value of 0.50 provides the smallest index of the temperature uniformity (i.e., the best temperature uniformity), in which case an average temperature is 572 degrees C. In addition, it can be seen from FIG. 16B that the power ratio value of 0.45 provides the smallest index of the temperature uniformity (i.e., the best temperature uniformity), in which case an average temperature is 677 degrees C.

Accordingly, in this specific example, in the above-described Step 104, an optimal power ratio for the control lower limit temperature value is 0.50 and this power ratio value and the corresponding average temperature of 572 degrees C. are stored. Similarly, an optimal power ratio for the control upper limit temperature value is 0.45 and this power ratio value and the corresponding average temperature of 677 degrees C. are stored.

Here, provided that a target temperature of a material substrate is 620 degrees C., the following calculation is performed in the above-described Step 106 according to the above equation (3).

$${T}_{620} = \frac{620 - 572}{677 - 572} \times ( 900 - 800 ) + 800 \qquad ( 6 )$$

As a result, 846 degrees C. is calculated as the control temperature value T₆₂₀.

In addition, the following calculation is performed in the above-described Step 106 according to the above equation (4) using the control temperature value T₆₂₀.

$${R}_{620} = \frac{846 - 800}{900 - 800} \times ( 0.45 - 0.50 ) + 0.50 \qquad ( 7 )$$

As a result, 0.477 is calculated as the power ratio value R₆₂₀.

Next, when a verification process for the power ratio value R₆₂₀ calculated in Step 110 is performed, for example, a measurement result shown in FIG. 16C can be obtained. Here, assuming that a verification interval is 0.01, 0.475 to 0.479 is measured as a power ratio value close to the power ratio value R₆₂₀. The measurement result of FIG. 16C reveals that a power ratio value of 0.477 provides the smallest index of the temperature uniformity (i.e., the best temperature uniformity) and a power ratio value as a control parameter for a target temperature of 620 degrees C. may, therefore, be set to 0.477. A control temperature value used at that time may be set to 846 degrees C. which corresponds to the control temperature value T₆₂₀.

While the present disclosure has been described above by way of exemplary embodiments, the present disclosure may be applied to apparatuses for processing glass substrates, such as an LCD apparatus, in addition to semiconductor manufacturing apparatuses. In addition, a film forming process includes, for example, a CVD, a PVD, a process of forming an oxide film or a nitride film, a process of forming a film containing metal, etc. In addition, the present disclosure may also be applied to other substrate processing apparatuses (such as an exposure apparatus, a lithographic apparatus, a coating applicator, a CVD apparatus using plasma, etc.).

### INDUSTRIAL APPLICABILITY

The present disclosure can be applied to an apparatus including a substrate heating part including at least two regions for heating a substrate, a power supply part for supplying power to the at least two regions, and a control device for adjusting the power supplied by the power supply part and controlling the substrate heating part such that the temperature of the substrate reaches a predetermined target temperature.

According to the present disclosure in some embodiments, it is possible to further shorten a time taken to acquire a control factor including a power ratio value to achieve desired temperature uniformity, as compared to conventional techniques.

While certain embodiments have been described, these embodiments have been presented by way of example only, and are not intended to limit the scope of the disclosures. Indeed, the novel methods and apparatuses described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus comprising:
a substrate heating part including a plurality of regions and being configured to heat a substrate;
a power supply part configured to supply power to the plurality of regions; and
a control device configured to adjust the power supplied by the power supply part and control the substrate heating part such that the temperature of the substrate reaches a predetermined target temperature,
wherein the control device:
measures a temperature of the substrate while controlling the substrate heating part such that the temperature of the substrate reaches a first control temperature higher than the target temperature using power supplied by the power supply part to each of the plurality of regions, the power supplied to one of the plurality of regions being determined according to the product of reference power supplied to the other of the plurality of regions and a power ratio value, and selects the power ratio value providing the best temperature uniformity in the plane of the substrate among results of the measurement and a temperature average value for the selected power ratio value;
measures the temperature of the substrate for a second control temperature lower than the target temperature, like the first control temperature, and selects the power ratio value providing the best temperature uniformity in the plane of the substrate among results of the measurement and a temperature average value for the selected power ratio value; and
calculates a control temperature and the power ratio value for the target temperature based on the selected temperature average value and the power ratio value for each of the first control temperature and the second control temperature.

2. A non-transitory computer-readable recording medium that stores a program executed in a substrate processing apparatus comprising: a substrate heating part including a plurality of regions and being configured to heat a substrate; a power supply part configured to supply power to the plurality of regions; and a control device configured to adjust the power supplied by the power supply part and control the substrate heating part such that the temperature of the substrate reaches a predetermined target temperature, and that readably stores a control parameter acquisition program that causes a computer to perform a process comprising:
a first step of measuring a temperature of the substrate while controlling the substrate heating part such that the temperature of the substrate reaches a first control temperature higher than the target temperature using power supplied by the power supply part to each of the plurality of regions, the power supplied to one of the plurality of regions being determined according to the product of reference power supplied to the other of the plurality of regions and a power ratio value, and selecting the power ratio value providing the best temperature uniformity in the plane of the substrate among, results of the measurement and a temperature average value for the selected power ratio value;
a second step of measuring the temperature of the substrate for a second control temperature lower than the target temperature, like the first control temperature, and selecting the power ratio value providing the best temperature uniformity in the plane of the substrate among results of the measurement and a temperature average value for the selected power ratio value; and
a third step of calculating a control temperature and the power ratio value for the target temperature based on the temperature average value and the power ratio value selected in the first step and the second step for each of the first control temperature and the second control temperature.

3. A method for manufacturing a semiconductor device executed in a substrate processing apparatus comprising: a substrate heating part including a plurality of regions and being configured to heat a substrate; a power supply part configured to supply power to the plurality of regions; and a control device configured to adjust the power supplied by the power supply part and control the substrate heating part such that the temperature of the substrate reaches a predetermined target temperature, the method comprising:
a first step of measuring a temperature of a substrate while controlling the temperature of the substrate such that the temperature of the substrate reaches a first control temperature higher than a predetermined target temperature using power supplied to each of the plurality of regions, the power supplied to one of the plurality of regions being determined according to the product of reference power supplied to the other of the plurality of regions and a power ratio value, and selecting the power ratio value providing the best temperature uniformity in the plane of the substrate among results of the measurement and a temperature average value for the selected power ratio value;
a second step of measuring the temperature of the substrate for a second control temperature lower than the target temperature, like the first control temperature, and selecting a power ratio value providing the best temperature uniformity in the plane of the substrate among results of the measurement and a temperature average value for the selected power ratio value;
a third step of calculating a control temperature and the power ratio value for the target temperature based on the temperature average value and the power ratio value selected in the first step and the second step for each of the first control temperature and the second control temperature; and
a fourth step of controlling the temperature of the substrate to reach the target temperature using control factors including the control temperature and the power ratio value calculated in the third step.

4. The method of claim 3, further comprising:
measuring the temperature of the substrate while controlling the temperature of the substrate such that the temperature of the substrate reaches the control temperature calculated in the third step for each of the plurality of power ratio values selected based on the power ratio value calculated in the third step, and extracting the power ratio value providing the best temperature uniformity in the plane of the substrate among results of the measurement.

5. The method of claim 3, wherein the first step or the second step includes:
heating the substrate such that the temperature of the substrate reaches the first control temperature or the second control temperature;
measuring the temperature of the substrate at a plurality of positions on the substrate;
calculating a substrate temperature average value and a value serving as an index of the temperature uniformity in the plane of the substrate when the first control temperature or the second control temperature is set, based on the temperatures measured at the plurality of positions.

6. The method of claim 3, wherein the first step or the second step includes performing one cycle a predetermined number of times, the cycle including:
heating the substrate such that the temperature of the substrate reaches the first control temperature or the second control temperature;
measuring the temperature of the substrate at a plurality of positions on the substrate;
calculating a substrate temperature average value and a value serving as an index of the temperature uniformity in the plane of the substrate when the first control temperature or the second control temperature is set based on the temperatures measured at the plurality of positions.

7. The method of claim 6, wherein the predetermined number of times is the number of times by which the power ratio value is changed.

8. The substrate processing apparatus of claim 1, wherein the control device sets a lower limit temperature value of a temperature control range of the substrate heating part as the second control temperature and sets an upper limit temperature value of the temperature control range of the substrate heating part as the first control temperature, and calculates the control temperature and the power ratio value for the target temperature between the lower limit temperature value and the upper limit temperature value.

9. The substrate processing apparatus of claim 1, wherein the control device is configured to measure the temperature of the substrate while controlling the temperature of the substrate such that the temperature of the substrate reaches the calculated control temperature for each of the plurality of power ratio values selected based on the calculated power ratio value, and is configured to extract the power ratio value providing the best temperature uniformity in the plane of the substrate among results of the measurement.

10. The substrate processing apparatus of claim 9, wherein the control device calculates a control temperature value (T_{T}) as the control temperature according to the following equation,
$${T}_{T} = \frac{{A}_{T} - {A}_{L}}{{A}_{H} - {A}_{L}} \times ( {T}_{H} - {T}_{L} ) + {T}_{L}$$
where, A_{T} represents a substrate target temperature, A_{L} represents an average temperature for conditions of best temperature uniformity when measurement is repeated while changing a power ratio value for the lower limit temperature value, A_{H} represents an as temperature for conditions of best temperature uniformity when measurement is repeated while changing the power ratio value for the upper limit temperature value, T_{L} represents the lower limit temperature value, and T_{H} represents the upper limit temperature value.

11. The substrate processing apparatus of claim 10, wherein the control device calculates a power ratio value (R_{T}) for the target temperature according to the following equation,
$${R}_{T} = \frac{{T}_{T} - {T}_{L}}{{T}_{H} - {T}_{L}} \times ( {R}_{H} - {R}_{L} ) + {R}_{L}$$
where, R_{L} represents the power ratio value for conditions of best temperature uniformity when measurement is repeated while changing the power ratio value for the lower limit temperature value, and R_{H} represents the power ratio value for conditions of best temperature uniformity when measurement is repeated while changing the power ratio value for the upper limit temperature value.
